(19) United States
(12) Patent Application Publication
(10) Pub. No.: US 2024/0215157 A1
(43) Pub. Date: Jun. 27, 2024

(54) PRINTED CIRCUIT BOARD

(71) Applicant: SAMSUNG ELECTRO-MECHANICS CO., LTD., Suwon-si (KR)

(72) Inventors: Ki Ran PARK, Suwon-si (KR); Hyun Woo KWON, Suwon-si (KR); Tae Hong MIN, Suwon-si (KR); Sang Hyun HAN, Suwon-si (KR); Guh Hwan LIM, Suwon-si (KR); Yo Han SONG, Suwon-si (KR); Dong Keun LEE, Suwon-si (KR); Kyeong Yub JUNG, Suwon-si (KR); Eun Gyu JEONG, Suwon-si (KR); Yu Mi KIM, Suwon-si (KR)

(73) Assignee: SAMSUNG ELECTRO-MECHANICS CO., LTD., Suwon-si (KR)

(21) Appl. No.: 18/382,202

(22) Filed: Oct. 20, 2023

(30) Foreign Application Priority Data
Dec. 21, 2022 (KR) 10-2022-0180873

(51) Int. Cl. H05K 1/02; H05K 3/10; H05K 3/42

(52) U.S. Cl. CPC H05K 1/0298; H05K 3/108; H05K 3/425; H05K 2201/09509; H05K 2201/09563; H05K 2201/096; H05K 2203/072; H05K 2203/0723

(57) ABSTRACT

A printed circuit board includes: a first insulating layer; a via pad disposed on an upper surface of the first insulating layer; a second insulating layer disposed on the upper surface of the first insulating layer and having a via hole exposing at least a portion of an upper surface of the via pad; a conductor pattern disposed on the exposed upper surface of the via pad; and a via including a first metal layer covering at least a portion of each of a wall surface of the via hole, the exposed upper surface of the via pad, and the conductor pattern, and a second metal layer disposed on the first metal layer and disposed in at least a portion of the via hole.

### CROSS-REFERENCE TO RELATED APPLICATION (S)

This application claims benefit of priority to Korean Patent Application No. 10-2022-0180873 filed on Dec. 21, 2022 in the Korean Intellectual Property Office, the disclosure of which is incorporated herein by reference in its entirety.

### TECHNICAL FIELD

The present disclosure relates to a printed circuit board.

### BACKGROUND

A circuit of a printed circuit board may be formed by using a semi-additive process (SAP) method or a modified semi-additive process (MSAP) method. For example, the circuit including a via pad may be formed on a first insulating material by using the SAP or MSAP method. In addition, a second insulating material may be applied thereto, a via hole may then be processed, and via fill plating may be performed to form a multilayer circuit capable of interlayer connection. However, a dimple may occur due to plating deviation when performing the via fill plating. In this case, a product may entirely have lower flatness to lower a manufacturing yield of the board.

### SUMMARY

An aspect of the present disclosure may provide a printed circuit board with fewer dimples after via fill plating.

The present disclosure may provide a printed circuit board in which via fill plating is performed after forming a conductor pattern on a via pad exposed in via hole processing.

According to an aspect of the present disclosure, a printed circuit board may include: a first insulating layer; a via pad disposed on an upper surface of the first insulating layer; a second insulating layer disposed on the upper surface of the first insulating layer and having a via hole exposing at least a portion of an upper surface of the via pad; a conductor pattern disposed on the exposed upper surface of the via pad; and a via including a first metal layer covering at least a portion of each of a wall surface of the via hole, the exposed upper surface of the via pad, and the conductor pattern, and a second metal layer disposed on the first metal layer and disposed in at least a portion of the via hole.

According to another aspect of the present disclosure, a printed circuit board may include: a first board unit including a first wiring layer including a via pad, an insulating layer covering at least a portion of the first wiring layer and having a via hole exposing at least a portion of an upper surface of the via pad, and a via disposed in at least a portion of the via hole; and a second board unit disposed on an upper surface of the insulating layer and including a second wiring layer including a via land thinner than the via pad. The via pad and the via land may be connected to each other through the via, a conductor pattern may be disposed on the exposed upper surface of the via pad, and the via may cover at least a portion of the conductor pattern.

### BRIEF DESCRIPTION OF DRAWINGS

The above and other aspects, features and advantages of the present disclosure will be more clearly understood from the following detailed description taken in conjunction with the accompanying drawings, in which:

FIG. 1 is a block diagram schematically illustrating an example of an electronic device system;

FIG. 2 is a perspective view schematically illustrating an example of an electronic device;

FIG. 3 is a cross-sectional view schematically illustrating a printed circuit board according to an exemplary embodiment;

FIGS. 4 and 5 are cross-sectional views schematically illustrating modified examples of the printed circuit board of FIG. 3;

FIGS. 6A through 6I are process diagrams schematically illustrating an example of manufacturing the printed circuit board of FIG. 3;

FIG. 7 is a cross-sectional view schematically illustrating a printed circuit board according to another exemplary embodiment; and

FIG. 8 is a cross-sectional view schematically illustrating a via dimple.

### DETAILED DESCRIPTION

Hereinafter, exemplary embodiments of the present disclosure will now be described in detail with reference to the accompanying drawings.

### Electronic Device

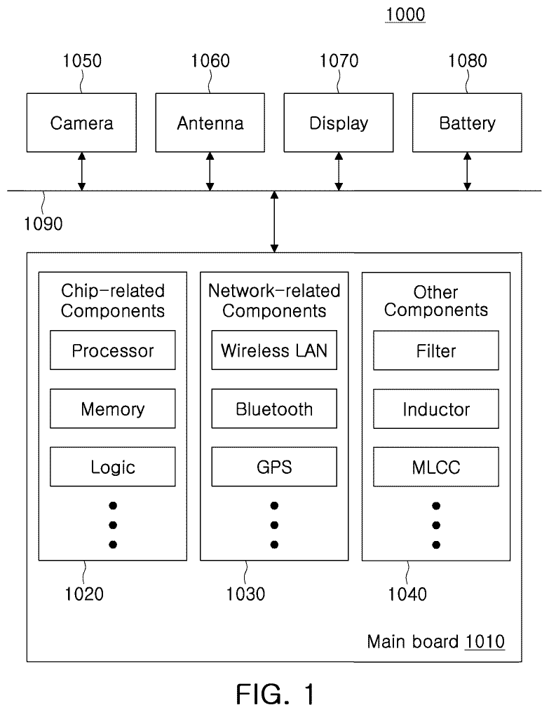

FIG. 1 is a block diagram schematically illustrating an example of an electronic device system.

Referring to FIG. 1, an electronic device 1000 may accommodate a main board 1010. The main board 1010 may include chip-related components 1020, network-related components 1030, other components 1040 and the like, which are physically or electrically connected thereto. These components may be connected to other electronic components described below to form various signal lines 1090.

The chip-related components 1020 may include a memory chip such as a volatile memory (for example, a dynamic random access memory (DRAM)), a non-volatile memory (for example, a read only memory (ROM)), or a flash memory; an application processor chip such as a central processor (for example, a central processing unit (CPU)), a graphics processor (for example, a graphics processing unit (GPU)), a digital signal processor, a cryptographic processor, a microprocessor, or a microcontroller; and a logic chip such as an analog-to-digital (ADC) converter or an application-specific integrated circuit (ASIC). However, the chip-related components 1020 are not limited thereto, and may also include other types of chip-related components. In addition, the chip-related components 1020 may be combined with each other. The chip-related component 1020 may be a package including the above-mentioned chip or electronic component.

The network-related components 1030 may include protocols such as wireless fidelity (Wi-Fi) (Institute of Electrical And Electronics Engineers (IEEE) 802.11 family, or the like), worldwide interoperability for microwave access (WiMAX) (IEEE 802.16 family, or the like), IEEE 802.20, long term evolution (LTE), evolution data only (Ev-DO), high speed packet access+(HSPA+), high speed downlink packet access+(HSDPA+), high speed uplink packet access+(HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth, 3G, 4G, and 5G protocols, and any other wireless and wired protocols designated after the above-mentioned protocols. However, the network-related components 1030 are not limited thereto, and may also include any of various other wireless or wired standards or protocols. In addition, the network-related components 1030 may be combined with the chip-related components 1020.

The other components 1040 may include a high frequency inductor, a ferrite inductor, a power inductor, ferrite beads, low temperature co-firing ceramics (LTCC), an electro magnetic interference (EMI) filter, a multi-layer ceramic condenser (MLCC) and the like. However, the other components 1040 are not limited thereto, and may further include a passive device in the form of a chip component used for various other purposes in addition to these components. In addition, the other components 1040 may be combined with the chip-related components 1020 or the network-related components 1030.

The electronic device 1000 may include another electronic component that may be or may not be physically or electrically connected to the main board 1010, based on a type of the electronic device 1000. Another electronic component may be a camera module 1050, an antenna module 1060, a display 1070, a battery 1080, etc. However, another electronic component is not limited thereto, and may be an audio codec, a video codec, a power amplifier, a compass, an accelerometer, a gyroscope, a speaker, a mass storage device (e.g., a hard disk drive), a compact disk (CD), a digital versatile disk (DVD), etc. In addition, another electronic component may be another electronic component used for various purposes, based on the type of the electronic device 1000.

The electronic device 1000 may be a smartphone, a personal digital assistant (PDA), a digital video camera, a digital still camera, a network system, a computer, a monitor, a tablet personal computer (PC), a laptop PC, a netbook PC, a television, a video game machine, a smartwatch, an automotive or the like. However, the electronic device 1000 is not limited thereto, and may also be any other electronic device processing data.

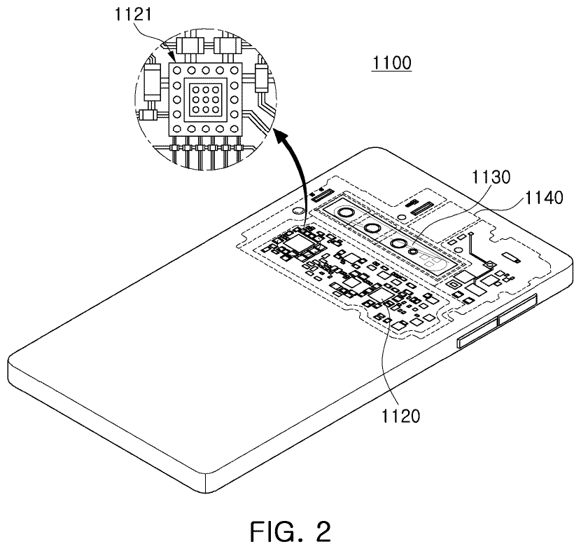

FIG. 2 is a perspective view schematically illustrating an example of an electronic device.

Referring to FIG. 2, the electronic device may be, for example, a smartphone 1100. The smartphone 1100 may accommodate a motherboard 1110, and various components 1120 may be physically or electrically connected to the motherboard 1110. In addition, the motherboard 1110 may accommodate other components that may or may not be physically or electrically connected thereto, such as the camera module 1130 or a speaker 1140. Some of the components 1120 may be the chip-related components, for example, a component package 1121, and are not limited thereto. The component package 1121 may be in the form of a printed circuit board on which electronic components including active components or passive components are surface mounted. Alternatively, the component package 1121 may be in the form of a printed circuit board in which the active components or the passive components are embedded. Meanwhile, the electronic device is not necessarily limited to the smartphone 1100, and may be another electronic device as described above.

### Printed Circuit Board

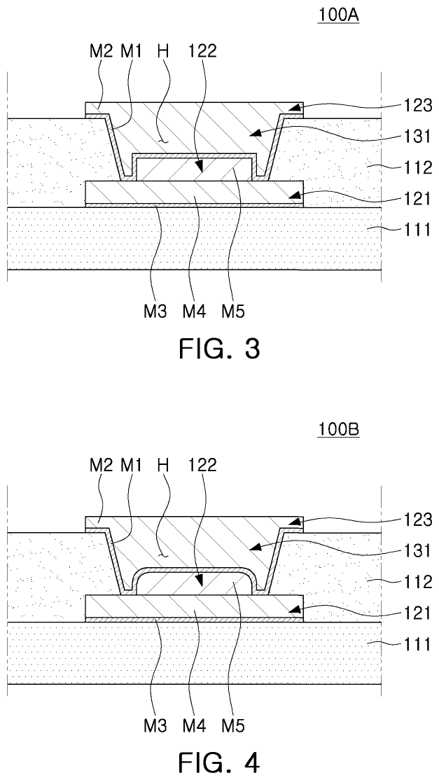

FIG. 3 is a cross-sectional view schematically illustrating a printed circuit board according to an exemplary embodiment.

Referring to FIG. 3, a printed circuit board 100A according to an exemplary embodiment may include: a first insulating layer 111; a via pad 121 disposed on an upper surface of the first insulating layer 111; a second insulating layer 112 disposed on the upper surface of the first insulating layer 111 and having a via hole H exposing at least a portion of an upper surface of the via pad 121; a conductor pattern 122 disposed on the exposed upper surface of the via pad 121; a via 131 filling at least a portion of the via hole H; and a via land 123 disposed on the via 131 to be connected to the via 131 and having at least a portion extended onto an upper surface of the second insulating layer 112. In this way, it is possible to suppress occurrence of a dimple by disposing the conductor pattern 122 on the via pad 121 in the via hole H to fill a portion of the via hole H in advance before performing fill plating for forming the via 131. Therefore, a product may entirely have improved flatness to improve a manufacturing yield of the board.

Meanwhile, the via 131 may be formed by the fill plating. For example, the via 131 may include a first metal layer M1 covering at least a portion of each of a wall surface of the via hole H, the exposed upper surface of the via pad 121, and the conductor pattern 122, and a second metal layer M2 disposed on the first metal layer M1 and filling at least a portion of the via hole H. The first metal layer M1 may be a seed layer, and may be, for example, an electroless plating layer or a sputtering layer. The second metal layer M2 may be a plating layer, for example, an electrolytic plating layer. The first and second metal layers M1 and M2 may each include copper (Cu), and a boundary between the layers may be distinguished from each other. The first metal layer M1 may have a thickness substantially constant, may be thinner than the second metal layer M2, and may cover the wall surface of the via hole H, the exposed upper surface of the via pad 121, and a surface of the conductor pattern 122. The second metal layer M2 may substantially completely fill the via hole H. In this manner, it is possible to suppress the occurrence of the dimples through the conductor pattern 122 even when the via 131 is formed by the fill plating.

Meanwhile, each of the via pad 121 and the conductor pattern 122 may include a metal material. For example, the via pad 121 and the conductor pattern 122 may each be formed by plating. For example, the via pad 121 may include a seed layer M3 formed by electroless plating or sputtering and a plating layer M4 formed by electrolytic plating, that is, a plurality of metal layers, and the conductor pattern 122 may include a plating layer M5 formed by electrolytic plating, that is, one metal layer. As such, the via pad 121 and the conductor pattern 122 may be formed by using a semi-additive process (SAP) method or a modified semi-additive process (MSAP) method, and thus be easily formed relatively simply and at a lower cost.

Meanwhile, the conductor pattern 122 may protrude from the upper surface of the via pad 121, and cover the central portion of the via pad 121. It is possible to secure a more excellent anti-dimple effect through this disposition.

Meanwhile, the conductor pattern 122 may have a substantially rectangular shape based on a cross section of the board. For example, the conductor pattern 122 may have the substantially rectangular shape based on the cross section. However, the shape of the conductor pattern 122 is not limited thereto, and may be variously changed as described below.

Meanwhile, the via land 123 may be thinner than the via pad 121. Even in this case, the via land 123 may have a substantially flat upper surface due to the fewer dimples. For example, more dimples may occur when filling the via hole H having a greater diameter by the fill plating and forming a thin circuit connected thereto. However, even in this case, it is possible to effectively suppress the occurrence of the dimples by disposing the conductor pattern 122 on the via pad 121 in the via hole H.

Meanwhile, the via land 123 may be formed integrally with the via 131 by plating, and thus include the first and second metal layers M1 and M2. The first metal layer M1 may be extended onto the upper surface of the second insulating layer 112, and the second metal layer M2 may be disposed on the first metal layer M1.

Hereinafter, the description describes the components of the printed circuit board 100A according to an exemplary embodiment in more detail with reference to the drawings.

The first and second insulating layers 111 and 112 may each include an insulating material. The insulating material may include a thermosetting resin such as an epoxy resin or a thermoplastic resin such as polyimide, or a material including an inorganic filler, an organic filler, or a glass fiber (i.e., glass fiber, glass cloth or glass fabric) together with this resin. The insulating material may be a photosensitive material or a non-photosensitive material. For example, each of the first and second insulating layers 111 and 112 may use the insulating material such as prepreg (PPG) or resin coated copper (RCC), is not limited thereto, and may also use Ajinomoto build-up film (ABF), photo imagable dielectric (PID), or the like. If necessary, each of the first and second insulating layers 111 and 112 may use another polymer material having excellent rigidity.

The via pad 121 may include a metal material. The metal material may use copper (Cu), aluminum (Al), silver (Ag), tin (Sn), gold (Au), nickel (Ni), lead (Pb), titanium (Ti), or alloys thereof. The via pad 121 may perform various functions based on a design thereof. For example, the via pad 121 may include a ground via pad, a power via pad, a signal via pad, or the like. Here, the signal via pad may include a via pad providing an electrical path for various signals other than the ground via pad, the power via pad, and the like, for example, a data signal. The via pad 121 may include the electroless plating layer (or chemical copper) and the electrolytic plating layer (or electrolytic copper). Alternatively, the via pad 121 may include a metal foil (or copper foil) and the electrolytic plating layer (or electrolytic copper). Alternatively, the via pad 121 may include the metal foil (or copper foil), the electroless plating layer (or chemical copper), and the electrolytic plating layer (or electrolytic copper). The via pad 121 may include the sputtering layer instead of the electroless plating layer (or chemical copper), or include both the layers, if necessary.

The conductor pattern 122 may include a metal material. The metal material may use copper (Cu), aluminum (Al), silver (Ag), tin (Sn), gold (Au), nickel (Ni), lead (Pb), titanium (Ti), or alloys thereof. The conductor pattern 122 may prevent the occurrence of the dimples after the fill plating of the via hole H. The conductor pattern 122 may include the electrolytic plating layer (or electrolytic copper). For example, the conductor pattern 122 may be formed on the via pad 121 by electrolytic plating without a separate seed layer. The conductor pattern 122 may have a boundary distinguished from that of the via pad 121, is not limited thereto, and may be integrated with the via pad 121 with no boundary, if necessary.

The via land 123 may include a metal material. The metal material may use copper (Cu), aluminum (Al), silver (Ag), tin (Sn), gold (Au), nickel (Ni), lead (Pb), titanium (Ti), or alloys thereof. The via land 123 may perform various functions based on a design thereof. For example, the via land 123 may include a ground via land, a power via land, a signal via land, or the like. Here, the signal via land may include a via land providing an electrical path for various signals other than the ground via land, the power via land, and the like, for example, the data signal. The via land 123 may include the electroless plating layer (or chemical copper) and the electrolytic plating layer (or electrolytic copper). Alternatively, the via land 123 may include the metal foil (or copper foil), the electroless plating layer (or chemical copper), and the electrolytic plating layer (or electrolytic copper). The via land 123 may include the sputtering layer instead of the electroless plating layer (or chemical copper), or include both the layers, if necessary. The via land 123 may also function as the via pad if necessary when applied to a more multilayer board.

The via 131 may include a metal material. The metal material may use copper (Cu), aluminum (Al), silver (Ag), tin (Sn), gold (Au), nickel (Ni), lead (Pb), titanium (Ti), or alloys thereof. The via 131 may perform various functions based on a design thereof. For example, the via 131 may include a ground via, a power via, a signal via, or the like. Here, the signal via may include a via for electrical connection between various signals other than the ground via, the power via, and the like, for example, the data signals. The via 131 may be tapered. For example, the via 131 may be tapered so that a width of a lower side connected to the via pad 121 is smaller than a width of an upper side connected to the via land 123 based on the cross section. The via 131 may be formed together with the via land 123 through the same plating method as that of the via land 123. The via 131 and the via land 123 may be integrated with each other, and are not limited thereto. The via 131 may include the electroless plating layer (or chemical copper) and the electrolytic plating layer (or electrolytic copper). The via 131 may include the sputtering layer instead of the electroless plating layer (or chemical copper), or include both the layers, if necessary.

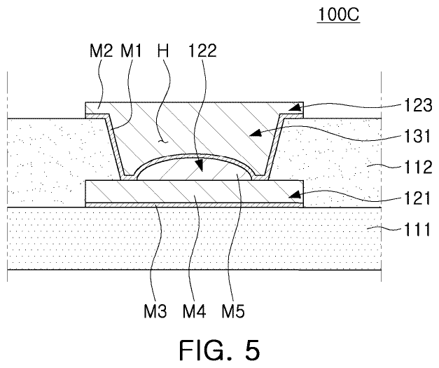

FIGS. 4 and 5 are cross-sectional views schematically illustrating modified examples of the printed circuit board of FIG. 3.

Referring to FIGS. 4 and 5, printed circuit board 100B or 100C according to the modified example may differ from the printed circuit board 100A according to an exemplary embodiment only in a shape of the conductor pattern 122. For example, as shown in FIG. 4, the conductor pattern 122 may have a rectangular shape in which an upper corner is non-vertical and rounded based on the cross section. Alternatively, as shown in FIG. 5, the conductor pattern 122 may have a round shape in which the central portion is convex based on the cross section. As such, the conductor pattern 122 may have various shapes to more effectively prevent the dimples.

Other contents are substantially the same as those described in the above-described printed circuit board 100A according to an exemplary embodiment, and the description thus omits redundant descriptions thereof.

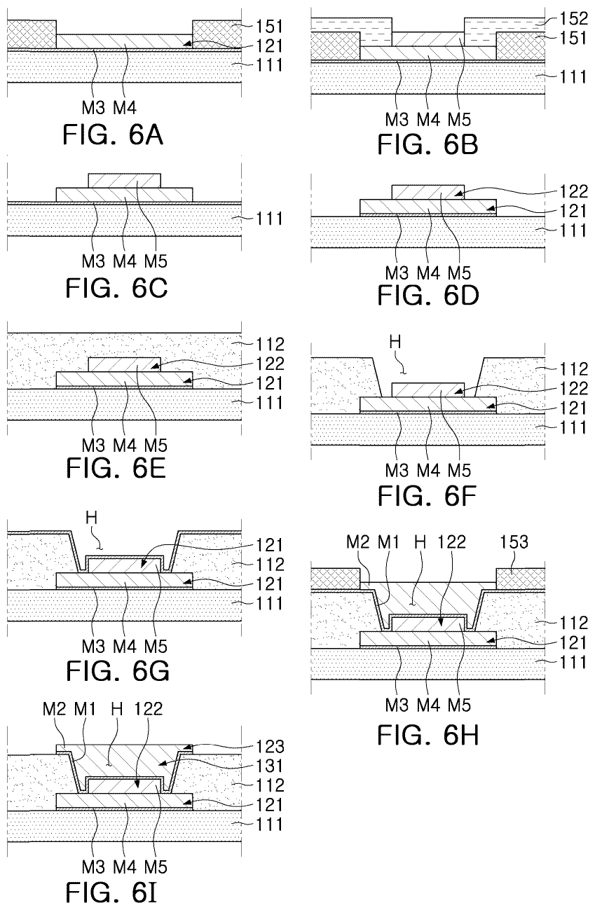

FIGS. 6A through 6I are process diagrams schematically illustrating an example of manufacturing the printed circuit board of FIG. 3.

Referring to FIG. 6A, a via pad 121 may be formed on the first insulating layer 111. For example, the via pad 121 may be formed by forming the seed layer M3 on the first insulating layer 111 by electroless plating or sputtering, forming a first dry film 151 on the seed layer M3, then forming a first opening by exposing and developing the first dry film 151 by using a photolithography method, and then forming a plating layer M4 on the seed layer M3 exposed through the first opening by electrolytic plating.

Referring to FIG. 6B, the conductor pattern 122 may be formed on the via pad 121. For example, the conductor pattern 122 may be formed by forming a second dry film 152 on the first dry film 151 and the via pad 121, then exposing and developing the second dry film 152 by using the photolithography method to form a second opening having a width smaller than that of the first opening based on the cross section, and then forming a plating layer M5 on the via pad 121 exposed through the second opening by electrolytic plating.

Referring to FIG. 6C, the first and second dry films 151 and 152 may be peeled off. The dry films 151 and 152 may be peeled off using a well-known peeling solution.

Referring to FIG. 6D, the remaining seed layer M3 on the first insulating layer 111 may be removed. The seed layer M3 may be removed by flash etching.

Referring to FIG. 6E, the second insulating layer 112 may be stacked on the first insulating layer 111. The second insulating layer 112 may be formed by stacking the insulating material in a non-cured film state, then applying a liquid insulating material thereto, and then curing the same or the like, and is not limited thereto.

Referring to FIG. 6F, the via hole H may be processed in the second insulating layer 112. The via hole H may be laser processed, is not limited thereto, and use the photolithography method based on a material of the second insulating layer 112. The via hole H may expose at least a portion of the upper surface of the via pad 121 and at least a portion of each of the upper surface and side surface of the conductor pattern 122. The via hole H may also have a structure in the above-mentioned modified examples by performing desmear or soft etching after processing the via hole H, and removing at least a portion of the conductor pattern 122 in a soft etching process.

Referring to FIG. 6G, the first metal layer M1 may be formed on the second insulating layer 112, the wall surface of the via hole H, the exposed upper surface of the via pad 121, and the conductor pattern 122. The first metal layer M1 may be formed by electroless plating or sputtering.

Referring to FIG. 6H, the second metal layer M2 may be formed on the first metal layer M1. For example, the via 131 and the via land 123 may be formed by forming a third dry film 153 on the first metal layer M1, then exposing and developing the dry third film 153 by using the photolithography method to form a third opening, and then forming the second metal layer M2 on the first metal layer M1 exposed through the third opening by electrolytic plating. Here, even when the via land 123 is thinly plated while filling the via hole H, it is possible to effectively prevent the occurrence of the dimples on the upper surface of the via land 123 through the conductor pattern 122 formed in the via hole H.

Referring to FIG. 6I, the third dry film 153 may be peeled off, and the remaining first metal layer M1 on the second insulating layer 112 may be removed. The third dry film 153 may be peeled off using the known peeling solution. The first metal layer M1 may be removed by flash etching.

Through this process using a series of methods, the printed circuit board 500A according to another exemplary embodiment described above may be manufactured. Other contents are substantially the same as those described in the above-described printed circuit board 100A according to an exemplary embodiment, and the description thus omits redundant descriptions thereof.

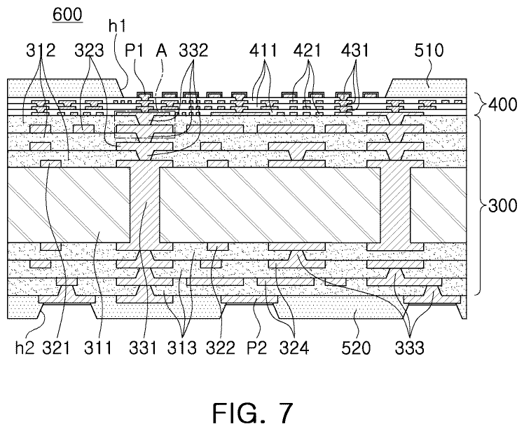

FIG. 7 is a cross-sectional view schematically illustrating a printed circuit board according to another exemplary embodiment.

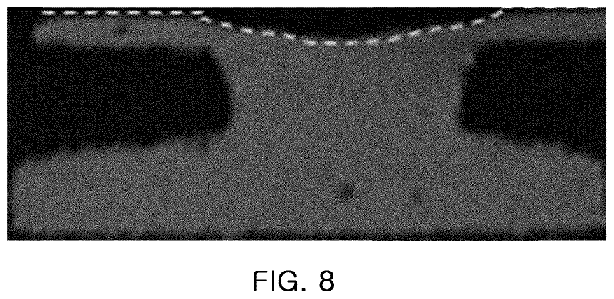

FIG. 8 is a cross-sectional view schematically illustrating the via dimple.

Referring to FIG. 7, a printed circuit board 600 according to another exemplary embodiment may include a first board unit 300, a second board unit 400 disposed on the first board unit 300, a first resist layer 510 disposed on the second board unit 400, or a second resist layer 520 disposed on a surface of the first board unit 300 that is opposite to its surface on which the second board unit 400 is disposed. The first board unit 300 may be a general multilayer board, and the second board unit 400 may be a build-up board including a microcircuit formed on the first board unit 300. Here, the structure of the above-described printed circuit board 100A, 100B, or 100C may be applied to an interlayer connection structure A at a boundary between the first and second board units 300 and 400. For example, the above-described conductor pattern may be disposed on an upper surface of a via pad included in the interlayer connection structure A that is exposed from a via hole, and the via may cover at least a portion of the conductor pattern while filling at least a portion of the via hole. In addition, a via land connected to the via may be thinner than the via pad.

Meanwhile, system integration in terms of a packages is in progress for an improved integration level of a semiconductor as the electronic device has a smaller size and higher performance. In a case of a latest high-end product, technology is developed in which the printed circuit board and a semiconductor chip are in contact with each other using a silicon interposer. However, as the product is required to have the increased size and number of the semiconductor chips, the silicon interposers are also required to have increased size and number, which leads to an increase in cost. Therefore, it is necessary to consider a structure in which the microcircuit is implemented on the outermost side of the board to be directly connected to a die without using the silicon interposer. For example, a multilayer build-up board including the microcircuit may be formed on one side of the multilayer core-type board. In this case, when plating a boundary between the core-type board and the build-up board, it may be required to fill the via hole having a great diameter by fill plating and simultaneously form the thin microcircuit. However, in this case, the dimples may occur as exemplified in FIG. 8. When these dimples are accumulated, an imbalance in flatness of the product may eventually occur, which results in non-connection and poor bonding between the package board and the semiconductor chip during their connection process.

On the other hand, the printed circuit board 600 according to another exemplary embodiment may have a structure that may replace that of the interposer by forming, for example, the second board unit 400 which is a coreless-type multilayer build-up board including the microcircuit, on the first board unit 300 which is a core-type multilayer board. Even in this case, it is possible to effectively suppress the occurrence of the dimple by applying the anti-dimple structure of the above-described printed circuit board 100A, 100B, or 100C to the interlayer connection structure A at the boundary between the first and second board units 300 and 400. Through this configuration, it is possible to expect higher package board production yield and packaging yield by improving the flatness of the entire products.

Meanwhile, a build-up wiring layer 421 included in the second board unit 400 may have a higher wiring density than core wiring layers 321 and 322 or build-up wiring layers 323 and 324, included in the first board unit 300. For example, the build-up wiring layer 421 of the second board unit 400 may include a higher-density wiring with a relatively fine pitch, and the core wiring layers 321 and 322 or build-up wiring layers 323 and 324 of the first board unit 300 may each include a lower-density wiring. For example, the build-up wiring layer 421 of the second board unit 400 may have smaller wiring thickness, lines/space, pitch, or the like than the core wiring layers 321 and 322 or build-up wiring layers 323 and 324 of the first board unit 300. In addition, an insulation distance between the build-up wiring layers 421 disposed on different layers of the second board unit 400 may also be smaller than an insulation distance between the core wiring layers 321 and 322 or the build-up wiring layers 323 and 324, disposed on different layers of the first board unit 300.

Hereinafter, the description describes the components of the printed circuit board 600 according to another exemplary embodiment in more detail with reference to the drawings.

The first board unit 300 may be the core-type multilayer board. For example, the first board unit 300 may include a core insulating layer 311, the first and second core wiring layers 321 and 322 respectively disposed on upper and lower surfaces of the core insulating layer 311, a through via layer 331 passing through the core insulating layer 311 and connecting the first and second core wiring layers 321 and 322 to each other, a plurality of first build-up insulating layers 312 disposed on the upper surface of the core insulating layer 311, the plurality of first build-up wiring layers 323 respectively disposed on or in the plurality of first build-up insulating layers 312, the plurality of first connection via layers 332 each passing through at least one of the plurality of first build-up insulating layers 312 and each connected to at least one of the plurality of first build-up wiring layers 323, a plurality of second build-up insulating layers 313 disposed on the lower surface of the core insulating layer 311, the plurality of second build-up wiring layers 324 respectively disposed on or in the plurality of second build-up insulating layers 313, and the plurality of second connection via layers 333 each passing through at least one of the plurality of second build-up insulating layers 313 and each connected to at least one of the plurality of second build-up wiring layers 324.

The core insulating layer 311 may include an insulating material. The insulating material may use a thermosetting resin such as an epoxy resin or a thermoplastic resin such as polyimide, a material in which this insulating resin is mixed with an inorganic filler such as silica, a resin impregnated into a core material such as a glass fiber (i.e., glass fiber, glass cloth or glass fabric) together with the inorganic filler, for example, copper clad laminate (CCL), or the like, and is not limited thereto. The core insulating layer 311 may have a thickness greater than each thickness of the first and second build-up insulating layers 312 and 313, and is not limited thereto.

Each of the first and second build-up insulating layers 312 and 313 may include an insulating material. The insulating material may use the thermosetting resin such as the epoxy resin or the thermoplastic resin such as the polyimide, the material in which this insulating resin is mixed with the inorganic filler such as silica, the resin impregnated into the core material such as the glass fiber (i.e., glass fiber, glass cloth or glass fabric) together with the inorganic filler, for example, Ajinomoto build-up film (ABF), prepreg, resin coated copper (RCC), or the like, and is not limited thereto. The first and second build-up insulating layers 312 and 313 are not limited to a specific number of layers, may have the same number of layers, and are not limited thereto.

The first and second core wiring layers 321 and 322 may each include a metal material. The metal material may use copper (Cu), aluminum (Al), silver (Ag), tin (Sn), gold (Au), nickel (Ni), lead (Pb), titanium (Ti), or alloys thereof. The first and second core wiring layers 321 and 322 may each include an electroless plating layer (or chemical copper) and an electrolytic plating layer (or electrolytic copper), and are not limited thereto. The first and second core wiring layers 321 and 322 may each include a sputtering layer instead of chemical copper as the electroless plating layer. If necessary, the first and second core wiring layers 321 and 322 may each further include a copper foil. The first and second core wiring layers 321 and 322 may each perform various functions based on designs thereof. For example, the first and second core wiring layers 321 and 322 may each include a ground pattern, a power pattern, a signal pattern, or the like. Here, the signal pattern may include various signals other than the ground pattern, the power pattern, and the like, for example, a data signal. Each of these patterns may include a line pattern, a plane pattern, or a pad pattern.

Each of the first and second build-up wiring layers 323 and 324 may include a metal material. The metal material may use copper (Cu), aluminum (Al), silver (Ag), tin (Sn), gold (Au), nickel (Ni), lead (Pb), titanium (Ti), or alloys thereof. The first and second build-up wiring layers 323 and 324 may each include the electroless plating layer (or chemical copper) and the electrolytic plating layer (or electrolytic copper), and are not limited thereto. The first and second build-up wiring layers 323 and 324 may each include the sputtering layer instead of chemical copper as the electroless plating layer. If necessary, the first and second build-up wiring layers 323 and 324 may each further include the copper foil. The first and second build-up wiring layers 323 and 324 may each perform various functions based on designs thereof. For example, the first and second build-up wiring layers 323 and 324 may each include the ground pattern, the power pattern, the signal pattern, or the like. Here, the signal pattern may include various signals other than the ground pattern, the power pattern, and the like, for example, the data signal. Each of these patterns may include the line pattern, the plane pattern, or the pad pattern.

The through via layer 331 may include a through via. The through via may include a metal layer formed on a wall surface of a through hole and a plug filling the metal layer. The metal layer may include the metal material such as copper (Cu), aluminum (Al), silver (Ag), tin (Sn), gold (Au), nickel (Ni), lead (Pb), titanium (Ti), or alloys thereof. The plug may include ink including the insulating material. The metal layer may include the electroless plating layer (or chemical copper) and the electrolytic plating layer (or electrolytic copper), and is not limited thereto. The through via layer 331 may include the sputtering layer instead of chemical copper as the electroless plating layer. The through via layer 331 may perform various functions based on a design thereof. For example, the through via layer 331 may include a ground via, a power via, a signal via, or the like. Here, the signal via may include a via for transferring various signals other than the ground via, the power via, and the like, for example, the data signal.

The first and second connection via layers 332 and 333 may include microvias. The microvia may be a filled via that fills the via hole or a conformal via that is disposed along a wall surface of the via hole. The microvias may be disposed in a stacked type or a staggered type. Each of the first and second connection via layers 332 and 333 may include a metal material, and the metal material may be copper (Cu), aluminum (Al), silver (Ag), tin (Sn), gold (Au), nickel (Ni), lead (Pb), titanium (Ti), or alloys thereof. The first and second connection via layers 332 and 333 may each include the electroless plating layer (or chemical copper) and the electrolytic plating layer (or electrolytic copper), and are not limited thereto. The first and second connection via layers 332 and 333 may each include the sputtering layer instead of chemical copper as the electroless plating layer. The first and second connection via layers 332 and 333 may each perform various functions based on designs thereof. For example, the first and second connection via layers 332 and 333 may each include the ground via, the power via, the signal via, or the like. Here, the signal via may include the via for transferring various signals other than the ground via, the power via, and the like, for example, the data signal.

Meanwhile, the uppermost build-up insulating layer of the plurality of first build-up insulating layers 312 may be the second insulating layer 112 in the above-described printed circuit board 100A, 100B, or 100C. In addition, the uppermost build-up wiring layer of the plurality of first build-up wiring layers 323 may be a wiring layer including the via pad 121 in the above-described printed circuit board 100A, 100B, or 100C. In addition, the uppermost connection via layer of the plurality of first connection via layers 332 may include the via 131 in the above-described printed circuit board 100A, 100B, or 100C. However, the interlayer connection structure of the above-described printed circuit board 100A, 100B, or 100C is not limited thereto, and may also be applied to another layer.

The second board unit 400 may be the coreless-type multilayer build-up board including the microcircuit. For example, the second board unit 400 may include a plurality of third build-up insulating layers 411, the plurality of third build-up wiring layers 421 respectively disposed on or in the plurality of third build-up insulating layers 411, and a plurality of third connection via layers 431 each passing through at least one of the plurality of third build-up insulating layers 411 and each connected to at least one of the plurality of third build-up wiring layers 421.

The third build-up insulating layer 411 may include an insulating material. The insulating material may use the thermosetting resin such as the epoxy resin or the thermoplastic resin such as the polyimide, the material in which this insulating resin is mixed with the inorganic filler such as silica, the resin impregnated into the core material such as the glass fiber (i.e., glass fiber, glass cloth or glass fabric) together with the inorganic filler, for example, Ajinomoto build-up film (ABF), prepreg, resin coated copper (RCC), or the like, and is not limited thereto. The third build-up insulating layer 411 is not limited to a specific number of layers.

The third build-up wiring layer 421 may include a metal material. The metal material may use copper (Cu), aluminum (Al), silver (Ag), tin (Sn), gold (Au), nickel (Ni), lead (Pb), titanium (Ti), or alloys thereof. The third build-up wiring layer 421 may include the electroless plating layer (or chemical copper) and the electrolytic plating layer (or electrolytic copper), and is not limited thereto. The third build-up wiring layer 421 may include the sputtering layer instead of chemical copper as the electroless plating layer. If necessary, the third build-up wiring layer 421 may further include the copper foil. The third build-up wiring layer 421 may perform various functions based on a design thereof. For example, the third build-up wiring layer 421 may include the ground pattern, the power pattern, the signal pattern, or the like. Here, the signal pattern may include various signals other than the ground pattern, the power pattern, and the like, for example, the data signal. Each of these patterns may include the line pattern, the plane pattern, or the pad pattern.

The third connection via layer 431 may include a microvia. The microvia may be the filled via that fills the via hole or the conformal via that is disposed along the wall surface of the via hole. The microvias may be disposed in the stacked type or the staggered type. The third connection via layer 431 may include a metal material, and the metal material may include copper (Cu), aluminum (Al), silver (Ag), tin (Sn), gold (Au), nickel (Ni), lead (Pb), titanium (Ti), or alloys thereof. The third connection via layer 431 may include the electroless plating layer (or chemical copper) and the electrolytic plating layer (or electrolytic copper), and is not limited thereto. The third connection via layer 431 may include the sputtering layer instead of chemical copper as the electroless plating layer. The third connection via layer 431 may perform various functions based on a design thereof. For example, the third connection via layer 431 may include the ground via, the power via, the signal via, or the like. Here, the signal via may include the via for transferring various signals other than the ground via, the power via, and the like, for example, the data signal.

In addition, the lowermost build-up wiring layer of the plurality of third build-up wiring layers 421 may be a wiring layer including the via land 123 in the above-described printed circuit board 100A, 100B, or 100C. However, the interlayer connection structure of the above-described printed circuit board 100A, 100B, or 100C is not limited thereto, and may also be applied to another layer.

The first and second resist layers 510 and 520 may each include an insulating material, and the insulating material may use a liquid-type or film-type solder resist. However, the first or second resist layer 510 or 520 is not limited thereto, and may use another material. The first resist layer 510 may include a first opening h1 exposing at least a portion of each of a plurality of first outer pads P1 disposed on an upper surface of the uppermost build-up wiring layer of the second board unit 400. For example, one first opening h1 may expose at least a portion of each of the plurality of first outer pads P1. A first surface treatment layer may be formed on each of the plurality of first outer pads P1 exposed through each first opening h1. Each of the first surface treatment layers may cover the upper surface and side surface of each of the first outer pads P1. The second resist layer 520 may include a plurality of second openings h2 each exposing at least a portion of each of a plurality of second outer pads P2 disposed on a lower surface of the lowermost build-up wiring layer of the first board unit 300. For example, the plurality of second openings h2 may each expose at least a portion of each of the plurality of second outer pads P2. A second surface treatment layer may be formed on each of the plurality of second outer pads P2 exposed through each second opening h2. Each of the second surface treatment layers may cover a lower surface of each of the second outer pads P2.

As set forth above, the present disclosure may provide the printed circuit board with the fewer dimples after the via fill plating.

In the present disclosure, the thickness, line, space, pitch, or the like may be measured using a scanning microscope or an optical microscope, such as Olympus's optical microscope (×1000), based on the polished or cut cross section of the printed circuit board. When these figures are not constant, the figures may be compared with an average value of values measured at five random points.

In the present disclosure, a meaning of the expression, “substantially,” may be determined by including a minute difference caused by a process error. For example, substantially the same thicknesses may include not only a case where the thicknesses are completely the same, but also a case where the thicknesses are approximately the same due to the process error. In addition, to substantially completely fill may include a case where there is a fine space due to a void or the like. In addition, to be substantially flat may include a minor thickness variation.

In the present disclosure, the cross-sectional shape may be a cross-sectional shape of an object when the object is vertically cut or its cross-sectional shape when the object is viewed from a side. In addition, the planar shape may be a shape of an object when the object is horizontally cut, or its planar shape when the object is viewed from top or bottom.

In the present disclosure, a lower side, a lower portion, a lower surface, and the like, are used to refer to a direction toward a surface on which the semiconductor package including an organic interposer is mounted based on cross sections of the drawings, for convenience, while an upper side, an upper portion, an upper surface, and the like, are used to refer to an opposite direction to the direction. However, these directions are defined for convenience of explanation, and the scope of the claims is not particularly limited by the directions defined as described above.

In the present disclosure, connection between two components conceptually includes their indirect connection through a third component as well as their direct connection. In addition, a term “electrically connected” conceptually includes a physical connection and a physical disconnection. In addition, it may be understood that when an element is referred to with terms such as “first” and “second,” the element is not limited thereby. These terms are used only to distinguish the element from another element, and may not limit the sequence or importance of the elements. In some cases, a first element may be referred to as a second element without departing from the scope of the claims set forth herein. Similarly, a second element may also be referred to as a first element.

The term “an exemplary embodiment” used herein does not refer to the same exemplary embodiment, and is provided to emphasize each particular feature different from that of another exemplary embodiment. However, the exemplary embodiments provided herein may be implemented in combination with features of another exemplary embodiment. For example, a description of an element in a specific exemplary embodiment may be understood as its description in another exemplary embodiment even though the element is not described in another exemplary embodiment, unless an opposite or contradictory description is provided therein.

The terms used herein are used only to describe an exemplary embodiment rather than limiting the present disclosure. Here, a term of a singular number includes its plural number unless explicitly interpreted otherwise in context.

While the exemplary embodiments have been shown and described above, it will be apparent to those skilled in the art that modifications and variations could be made without departing from the scope of the present disclosure as defined by the appended claims.

What is claimed is:

1. A printed circuit board, the board comprising:
a first insulating layer;
a via pad disposed on an upper surface of the first insulating layer;
a second insulating layer disposed on the upper surface of the first insulating layer and having a via hole exposing at least a portion of an upper surface of the via pad;
a conductor pattern disposed on the exposed upper surface of the via pad; and
a via including a first metal layer covering at least a portion of each of a wall surface of the via hole, the exposed upper surface of the via pad, and the conductor pattern, and a second metal layer disposed on the first metal layer and disposed in at least a portion of the via hole.

2. The printed circuit board of claim 1, wherein the first metal layer includes at least one of an electroless plating layer and a sputtering layer, and
the second metal layer includes an electrolytic plating layer.

3. The printed circuit board of claim 2, wherein the first and second metal layers each include copper (Cu) and a boundary between the first and second metal layers are distinguished from each other.

4. The printed circuit board of claim 1, wherein the first metal layer is thinner than the second metal layer.

5. The printed circuit board of claim 4, wherein the first metal layer has a thickness substantially constant and continuously cover the wall surface of the via hole, the exposed upper surface of the via pad, and a surface of the conductor pattern, and
the second metal layer substantially completely fills the via hole.

6. The printed circuit board of claim 1, wherein the via pad includes a plurality of metal layers, and
the conductor pattern includes one metal layer.

7. The printed circuit board of claim 1, further comprising a via land disposed on the via to be connected to the via, and having at least a portion extended onto an upper surface of the second insulating layer,
wherein the via land includes the first and second metal layers.

8. The printed circuit board of claim 7, wherein an upper surface of the via land is substantially flat.

9. The printed circuit board of claim 7, wherein the via land is thinner than the via pad.

10. The printed circuit board of claim 1, wherein the conductor pattern protrudes from the upper surface of the via pad, and
the conductor pattern covers a central portion of the upper surface of the via pad.

11. The printed circuit board of claim 1, wherein the conductor pattern has a rectangular shape in which an upper corner is rounded based on a cross section of the printed circuit board.

12. The printed circuit board of claim 1, wherein the conductor pattern has a round shape in which a central portion is convex based on a cross section of the printed circuit board.

13. The printed circuit board of claim 1, wherein the conductor pattern has a rectangular shape based on a cross section of the printed circuit board.

14. The printed circuit board of claim 1, wherein the first metal layer is in contact with the via pad.

15. The printed circuit board of claim 1, wherein the conductor pattern is spaced apart from the wall surface of the via hole.

16. A printed circuit board, the board comprising:
a first board unit including a first wiring layer including a via pad, an insulating layer covering at least a portion of the first wiring layer and having a via hole exposing at least a portion of an upper surface of the via pad, and a via disposed in at least a portion of the via hole; and
a second board unit disposed on an upper surface of the insulating layer and including a second wiring layer including a via land thinner than the via pad,
wherein the via pad and the via land are connected to each other through the via,
a conductor pattern is disposed on the exposed upper surface of the via pad, and
the via covers at least a portion of the conductor pattern.

17. The printed circuit board of claim 16, wherein the second wiring layer has a higher wiring density than the first wiring layer.

18. The printed circuit board of claim 16, wherein the first board unit includes a core insulating layer, first and second core wiring layers respectively disposed on upper and lower surfaces of the core insulating layer, a through via layer passing through the core insulating layer and connecting the first and second core wiring layers to each other, a plurality of first build-up insulating layers disposed on the upper surface of the core insulating layer, a plurality of first build-up wiring layers respectively disposed on or in the plurality of first build-up insulating layers, a plurality of first connection via layers each passing through at least one of the plurality of first build-up insulating layers and each connected to at least one of the plurality of first build-up wiring layers, a plurality of second build-up insulating layers disposed on the lower surface of the core insulating layer, a plurality of second build-up wiring layers respectively disposed on or in the plurality of second build-up insulating layers, and a plurality of second connection via layers each passing through at least one of the plurality of second build-up insulating layers and each connected to at least one of the plurality of second build-up wiring layers,
the insulating layer and the first wiring layer are uppermost layers of the plurality of first build-up insulating layers and the plurality of first build-up wiring layers, respectively, and
the via is a portion of an uppermost layer of the plurality of first connection via layers.

19. The printed circuit board of claim 16, wherein the second board unit includes a plurality of third build-up insulating layers disposed on an upper surface of the insulating layer, a plurality of third build-up wiring layers respectively disposed on or in the plurality of third build-up insulating layers, and a plurality of third connection via layers respectively passing through at least one of the plurality of third build-up insulating layers and respectively connected to at least one of the plurality of third build-up wiring layers, and
the second wiring layer is a lowermost layer of the plurality of third build-up wiring layers.
